(19) United States
(12) Patent Application Publication
(10) Pub. No.: US 2009/0250760 A1
(43) Pub. Date: Oct. 8, 2009

(54) METHODS OF FORMING HIGH-K/METAL GATES FOR NFETS AND PFETS

(75) Inventors: Michael P. Chudzik, Danbury, CT (US); William K. Henson, Beacon, NY (US); Naim Moumen, Walden, NY (US); Dae-Gyu Park, Poughquaq, NY (US); Hongwen Yan, Somers, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 12/061,081

(22) Filed: Apr. 2, 2008

(51) Int. Cl. H01L 27/088; H01L 21/4763

(52) U.S. Cl. 257/368; 438/591; 257/E27.06

(57) ABSTRACT

Methods of forming high-k/metal gates for an NFET and PFET and a related structure are disclosed. One method includes recessing a PFET region; forming a first high-k dielectric layer and a first metal layer over the substrate; removing the first high-k dielectric layer and the first metal over the NFET region using a mask; forming a forming a second high-k dielectric layer and a second metal layer over the substrate, the first high-k dielectric layer being different then the second high-k dielectric layer and the first metal being different than the second metal; removing the second high-k dielectric layer and the second metal over the PFET region using a mask; depositing a polysilicon over the substrate; and forming a gate over the NFET region and the PFET region by simultaneously etching the polysilicon, the first high-k dielectric layer, the first metal, the second high-k dielectric layer and the second metal.

### BACKGROUND

1. Technical Field

The disclosure relates generally to integrated circuit (IC) chip fabrication, and more particularly, to methods of forming high-k/metal gates for NFETs and PFETs.

2. Background Art

High dielectric constant (high-k) and metal gates are increasingly being used for n-type field effect transistors (NFETs) and p-type FETs (PFETs). Typically, a particular metal is placed over the NFET region and another metal is placed over the PFET region. The high-k dielectrics used may also differ between the regions. A polysilicon is then deposited over a selected region and etched to form a gate from the polysilicon, the particular metal over the selected region and the high-k dielectric. This process is then repeated for the other region. A challenge in forming the different devices arises because the metals for the NFET and PFET regions etch at different rates, e.g., typically the NFET metal etches faster than the PFET metal. Consequently, preventing overetching into the substrate below the gates is difficult.

### SUMMARY

Methods of forming high-k/metal gates for an NFET and PFET and a related structure are disclosed. One method includes recessing a PFET region; forming a first high-k dielectric layer and a first metal layer over the substrate; removing the first high-k dielectric layer and the first metal over the NFET region using a mask; forming a forming a second high-k dielectric layer and a second metal layer over the substrate, the first high-k dielectric layer being different then the second high-k dielectric layer and the first metal being different than the second metal; removing the second high-k dielectric layer and the second metal over the PFET region using a mask; depositing a polysilicon over the substrate; and forming a gate over the NFET region and the PFET region by simultaneously etching the polysilicon, the first high-k dielectric layer, the first metal, the second high-k dielectric layer and the second metal.

A first aspect of the disclosure provides a method comprising: providing a substrate including an n-type field effect transistor (NFET) region and a p-type FET (PFET) region therein; recessing the PFET region; forming a first high dielectric constant (high-k) dielectric layer and a first metal layer over the substrate; removing the first high-k dielectric layer and the first metal over the NFET region using a mask; forming a second high dielectric constant (high-k) dielectric layer and a second metal layer over the substrate, the first high-k dielectric layer being different than the second high-k dielectric layer and the first metal layer being different than the second metal layer; removing the second high-k dielectric layer and the second metal layer over the PFET region using a mask; depositing a polysilicon over the substrate; and forming a gate over the NFET region and a gate over the PFET region by simultaneously etching the polysilicon, the first high-k dielectric layer, the first metal layer, the second high-k dielectric layer and the second metal layer.

A second aspect of the disclosure provides a structure comprising: a first gate for a p-type field effect transistor (PFET) including a first high dielectric constant (high-k) dielectric layer and a first metal layer; a second gate for an n-type field effect transistor (NFET) including a second high dielectric constant (high-k) dielectric layer and a second metal layer, the first high-k dielectric layer being different than the second high-k dielectric layer and the first metal layer being different than the second metal layer; and wherein a lower surface of the first gate is recessed compared to a lower surface of the second gate.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1-8 show embodiments of a method according to the disclosure, with FIG. 8 showing a structure according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

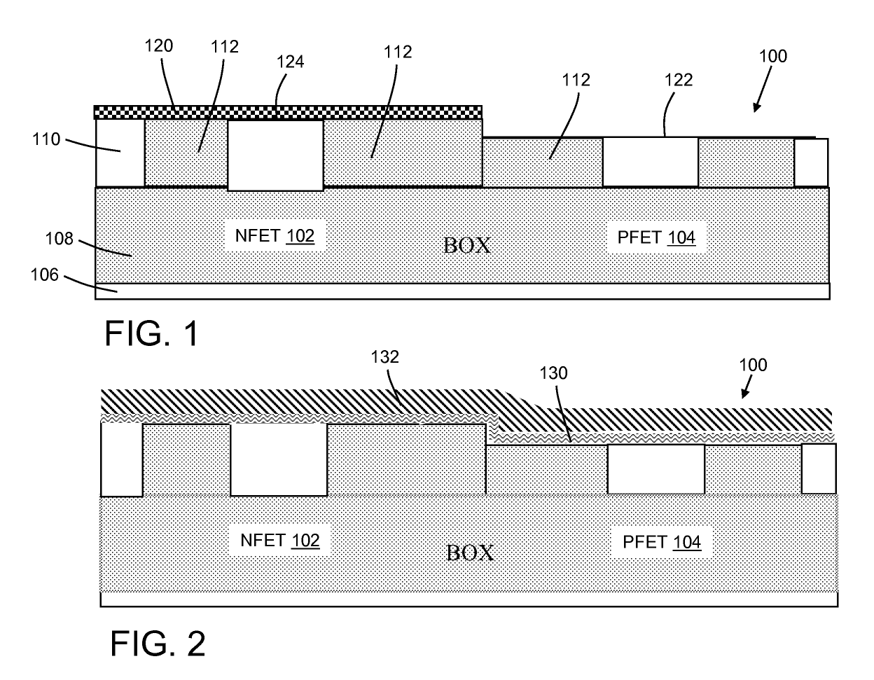

Referring to the drawings, FIG. 1 shows a process of providing a substrate 100 including an n-type field effect transistor (NFET) region 102 and a p-type FET (PFET) region 104 therein. Substrate 100 includes a semiconductor layer 106, having a buried insulator (e.g., buried oxide (BOX) layer 108 and a semiconductor-on-insulator (SOI) layer 110. Semiconductor layer 106 or SOI layer 110 may include but are not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). SOI layer 110 is segmented by trench isolations 112, e.g. of silicon oxide. NFET region 102 and PFET region 104 may otherwise include any now known or later developed structures or materials associated with an area in which an NFET or PFET, respectively, would be generated.

FIG. 1 also shows recessing PFET region 104, e.g., SOI layer 110 and trench isolations 112 of PFET region 104. This process may be performed, for example, by patterning a mask 120 over NFET region 102 and etching (e.g., reactive ion etch (RIE)) PFET region 104. As a result, an upper surface 122 of PFET region 104 is lower than an upper surface 124 of NFET region 102.

FIG. 2 shows forming a first high dielectric constant (high-k) dielectric layer 130 and a first metal layer 132 over substrate 100. First metal layer 132 may include but is not limited to: titanium nitride (TiN), tantalum nitride (TaN), tungsten nitride (WN), ruthenium (Ru) and/or titanium aluminum nitride (TiAlN), and first high-k dielectric layer 130 may include but is not limited to: hafnium aluminate (HfAlO), hafnium silicon oxide (HfSiO), hafnium zirconium oxide (HfZrO), hafnium oxide (HfO₂) and/or zirconium oxide (ZrO₂). Each material is selected to improve the performance of PFETs formed in PFET region 104. Each layer 130, 132 may be formed using a deposition technique that may include any now known or later developed techniques appropriate for the material to be deposited including but not limited to: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

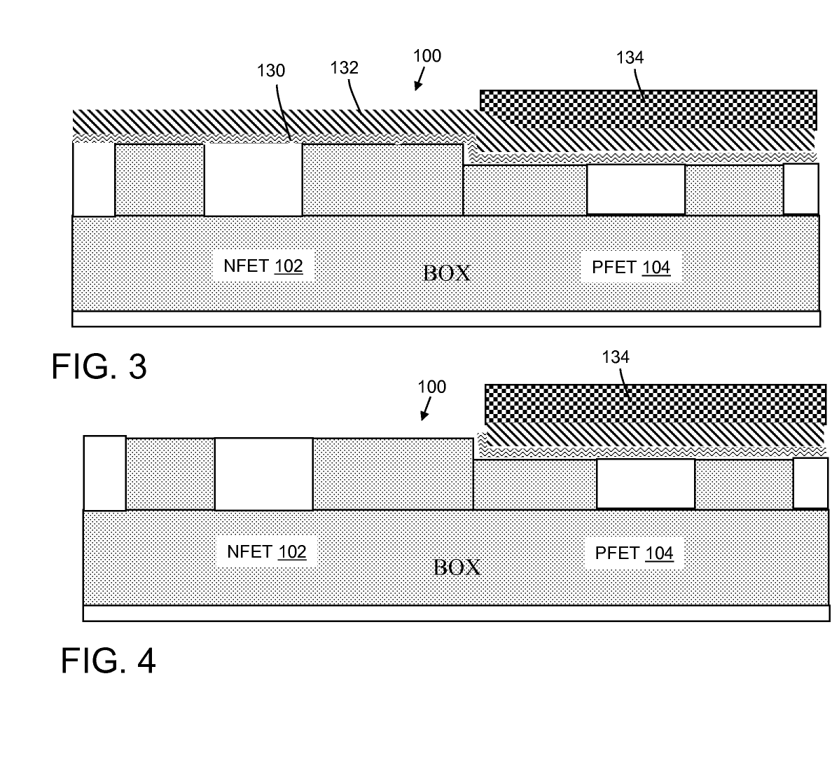

Referring to FIGS. 3-4, first high-k dielectric layer 130 and first metal layer 132 over NFET region 102 are removed using a mask 134, e.g., using a RIE or wet etch. Alternatively, only first metal layer 132 may be removed, leaving first high-k dielectric layer 130.

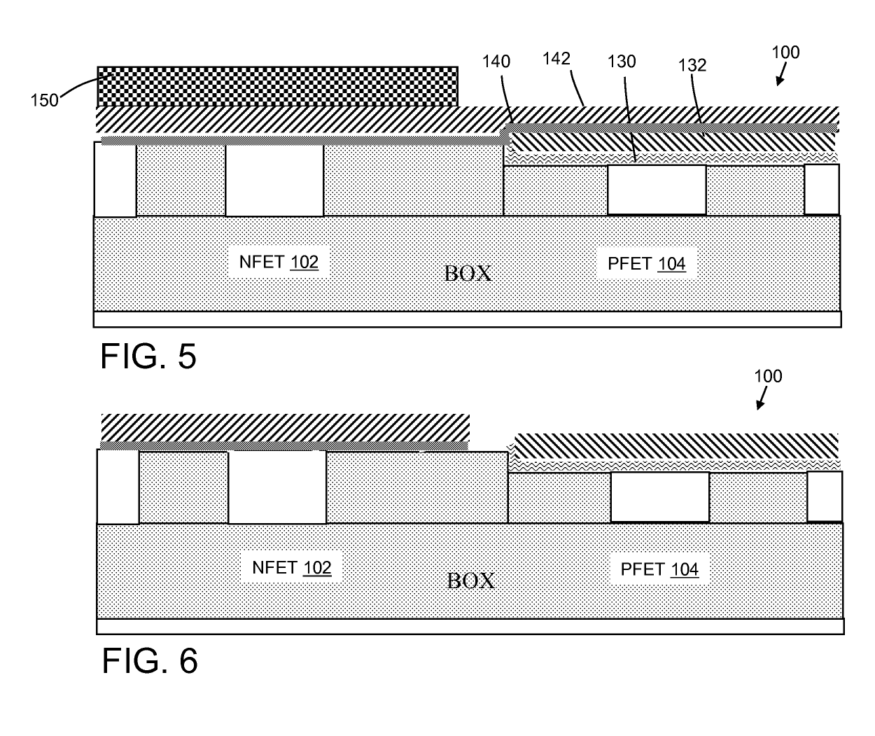

FIG. 5 shows forming a second high-k dielectric layer 140 and a second metal layer 142 over substrate 100. First high-k dielectric layer 130 is different than second high-k dielectric layer 140 and first metal layer 132 is different than second metal layer 142. For example, second metal layer 142 may include but is not limited to: tantalum nitride (TaN), tungsten nitride (WN) and/or titanium nitride (TiN), and second high-k dielectric layer 140 may include but is not limited to: hafnium oxide (HfO₂), hafnium lanthanum oxide (HfLaO), hafnium zirconium oxide (HfZrO), hafnium silicon oxide (HfSiO), zirconium oxide (ZrO₂) and/or lanthanum oxide (La₂O₃). Second metal layer 142 thus etches slower than first metal layer 132. Each material is selected to improve the performance of PFETs formed in PFET region 104. Each layer 140, 142 may be formed using any of the above-described deposition techniques.

In FIG. 6, second high-k dielectric layer 140 (FIG. 5) and second metal layer 142 (FIG. 5) are removed over PFET region 104 using a mask 150 (FIG. 5), e.g., by a RIE or wet etch.

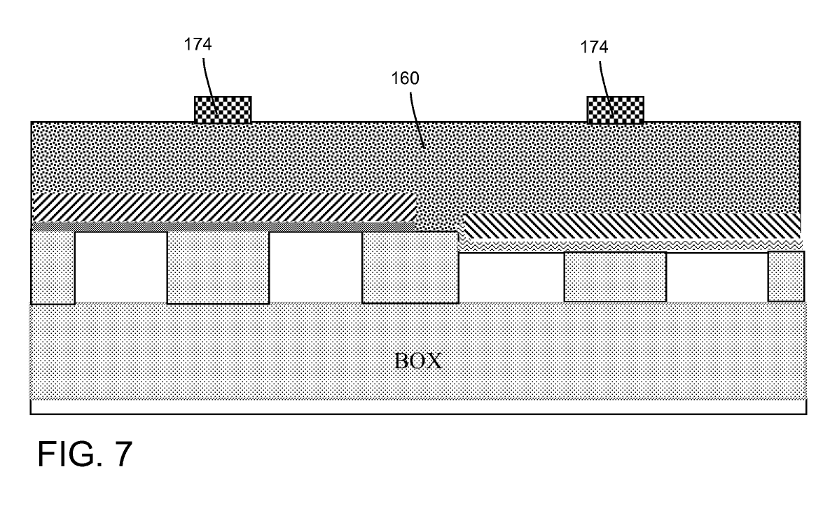

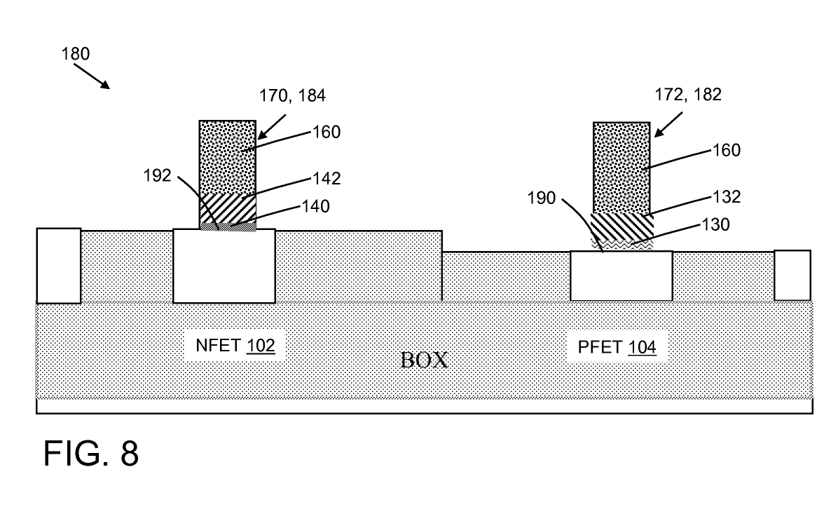

FIG. 7 shows depositing a polysilicon 160 over substrate 100, e.g., using any of the above-described deposition techniques. A planarization step (e.g., chemical mechanical polishing (CMP)) may be required at this stage. FIG. 8 shows forming a gate 170 over NFET region 102 and a gate 172 over PFET region 104 by simultaneously etching polysilicon 160, first high-k dielectric layer 130, first metal layer 132, second high-k dielectric layer 140 and second metal layer 142, e.g., using a mask 174 (FIG. 7).

FIG. 8 also shows a structure 180 including a first gate 172 for a PFET 182 including first high-k dielectric layer 130 and first metal layer 132. Structure 180 also includes a second gate 170 for an NFET 180 including second high-k dielectric layer 140 and second metal layer 142. As noted above, first high-k dielectric layer 130 is different than second high-k dielectric layer 140 and first metal layer 132 is different than the second metal layer 142. As shown in FIG. 8, a lower surface 190 of first gate 172 is recessed compared to a lower surface 192 of second gate 170.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A method comprising:
providing a substrate including an n-type field effect transistor (NFET) region and a p-type FET (PFET) region therein;
recessing the PFET region;
forming a first high dielectric constant (high-k) dielectric layer and a first metal layer over the substrate;
removing the first high-k dielectric layer and the first metal over the NFET region using a mask;
forming a second high dielectric constant (high-k) dielectric layer and a second metal layer over the substrate, the first high-k dielectric layer being different than the second high-k dielectric layer and the first metal layer being different than the second metal layer;
removing the second high-k dielectric layer and the second metal layer over the PFET region using a mask;
depositing a polysilicon over the substrate; and
forming a gate over the NFET region and a gate over the PFET region by simultaneously etching the polysilicon, the first high-k dielectric layer, the first metal layer, the second high-k dielectric layer and the second metal layer.

2. The method of claim 1, wherein the second metal layer etches slower than the first metal layer.

3. The method of claim 1, wherein the first metal layer is selected from the group consisting of: titanium nitride (TiN), tantalum nitride (TaN), tungsten nitride (WN), ruthenium (Ru) and titanium aluminum nitride (TiAlN), and the second metal layer is selected from the group consisting of: tantalum nitride (TaN), tungsten nitride (WN) and titanium nitride (TiN).

4. The method of claim 1, wherein the first high-k dielectric layer is selected from the group consisting of: hafnium aluminate (HfAlO), hafnium silicon oxide (HfSiO), hafnium zirconium oxide (HfZrO), hafnium oxide (HfO₂) and zirconium oxide (ZrO₂), and the second high-k dielectric layer is selected from the group consisting of: hafnium oxide (HfO₂), hafnium lanthanum oxide (HfLaO), hafnium zirconium oxide (HfZrO), hafnium silicon oxide (HfSiO), zirconium oxide (ZrO₂) and lanthanum oxide (La₂O₃).

5. A structure comprising:
a first gate for a p-type field effect transistor (PFET) including a first high dielectric constant (high-k) dielectric layer and a first metal layer;
a second gate for an n-type field effect transistor (NFET) including a second high dielectric constant (high-k) dielectric layer and a second metal layer, the first high-k dielectric layer being different than the second high-k dielectric layer and the first metal layer being different than the second metal layer; and
wherein a lower surface of the first gate is recessed compared to a lower surface of the second gate.
